(19) United States
(12) Patent Application Publication
(10) Pub. No.: US 2012/0068161 A1
(43) Pub. Date: Mar. 22, 2012

(54) METHOD FOR FORMING GRAPHENE USING LASER BEAM, GRAPHENE SEMICONDUCTOR MANUFACTURED BY THE SAME, AND GRAPHENE TRANSISTOR HAVING GRAPHENE SEMICONDUCTOR

(76) Inventors: Keon-Jae LEE, Daejeon-si (KR); In-Sung Choi, Daejeon-si (KR); Sung-Yool Choi, Daejeon-si (KR); Byung-Hee Hong, Suwon-si (KR)

(21) Appl. No.: 13/233,553

(22) Filed: Sep. 15, 2011

(30) Foreign Application Priority Data
Sep. 16, 2010 (KR) 10-2010-0091217
Sep. 17, 2010 (KR) 10-2010-0091599
Sep. 17, 2010 (KR) 10-2010-0091600
Jan. 11, 2011 (KR) 10-2011-0006115

(51) Int. Cl. H01L 29/66; B01J 19/12; H01L 21/268; B82Y 40/00; B82Y 30/00

(52) U.S. Cl. 257/29; 204/157.41; 438/535; 977/734; 977/842; 257/E21.347; 257/E29.168

(57) ABSTRACT

A method for forming graphene includes introducing a substrate and a carbon-containing reactant source into a chamber, and radiating a laser beam onto the substrate to decompose the carbon-containing reactant source and form graphene over the substrate using carbon atoms generated by decomposition of the carbon-containing reactant source. A carbon-containing gas (methane) decomposes upon radiation of a laser beam. The carbon-containing gas has a decomposition rate on the order of femtoseconds and the laser beam has a pulse on the order of nanoseconds or more. The graphene is grown in a single layer along the surface of the substrate. Then, the graphene is selectively patterned using a laser beam to form a desired pattern.

### CROSS-REFERENCE TO RELATED APPLICATIONS

The present application claims priority of Korean Patent Application Nos. 10-2010-0091217 filed on Sep. 16, 2010, 10-2010-0091599 filed on Sep. 17, 2010, 10-2010-0091600 filed on Sep. 17, 2010, and 10-2011-0006115 filed on Jan. 21, 2011. The disclosure of each of the foregoing applications is incorporated herein by reference in its entirety.

### BACKGROUND OF THE INVENTION

The present invention relates to a method for forming graphene using a laser beam, a graphene semiconductor manufactured by the same, and a graphene transistor having the graphene semiconductor, and more particularly, to a method for locally forming a high temperature area on a substrate using a laser beam for nanoseconds to form a desired graphene pattern on the substrate, and a device made by this method.

Graphene is a single-layered carbon structure that constitutes a two-dimensional lattice filled with carbon atoms. Graphene is a basic structure of graphite that is structured in varying numbers of dimensions. For example, graphene can be a basic structure of fullerene arranged in zero dimensions or a basic structure of nanotubes arranged either in one dimension or in three dimensions. In 2004, Novoselev et al. reported that they succeeded in obtaining free-standing single-layered graphene on a SiO₂/Si substrate. Graphene was experimentally discovered by a mechanical micro-segmentation method. In recent years, graphene is getting more attention from many research groups because of its unique physical properties (for example, a zero band gap) attributable to its honeycomb crystalline structure, its sub-lattice structure configured of two triangles that interfere with each other, its thickness, which is equivalent to one atom, and so on. Also, graphene has a unique carrier transmission property, which is a unique phenomenon that has not been observed before. For example, such phenomena as the Half-integer Quantum Hall Effect and a bipolar super-current transistor effect are attributable to the above-mentioned unique structure of graphene. Because of its low surface resistance, single-layered graphene is expected to replace conventional transparent conductive oxide layers such as ITO. However, it is difficult to form graphene in a single layer. Among some conventional methods, according to a liquid method, a graphene oxide film is made in solution and then reduced. According to a vapor method, methane and hydrogen gases are introduced into a chamber at high temperature. However, it is disadvantageous in that a high temperature condition is required, and it is difficult to obtain a single layer of graphene in a large size.

Graphene may replace silicon and be used as a next-generation semiconductor device when high quality single-layered graphene can be obtained and its band gap can be controlled. A technology forming graphene in a nanoribbon configuration to control its band gap was suggested. See Nature nanotechnology, Vol. 5, p. 321, 2010 (hereinafter, Prior Art 1). According to the Prior Art 1, a source, a drain, and a gate are connected through nanoribbon-shaped graphene. When voltage is applied to the gate, electrons flow through the nanoribbon-shaped graphene. However, it is difficult to precisely form nanoribbon-shaped graphene on a substrate. Also, it is extremely difficult to precisely control the band gap of graphene.

Another method for forming graphene is doping boron and nitrogen while the graphene is growing. See Adv. Material, Vol. 21, pp. 4726-4730, 2009 (hereinafter, Prior Art 2). However, this method is disadvantageous in that original graphene structure is destroyed in the course of doping, and thus the properties of the graphene are deteriorated. As such, research into the use of graphene as a semiconductor has been conducted, but it is still impossible to satisfactorily control the band gap of graphene. Research into the control of the band gap of graphene by forming graphene in a nano pattern or applying an electric field to a substrate is being undertaken. However, the results are still unsatisfactory.

Meanwhile, because of its crystalline structure, which is similar to that of graphene, boron nitride (BN) is attracting attention as a new electrical material. However, methods of forming a boron nitride layer, for example, a chemical vapor deposition method, are limited.

### SUMMARY OF THE INVENTION

An embodiment of the present invention is directed to a method for forming graphene on a large scale.

Another embodiment of the present invention is directed to a semiconductor device and a transistor using the graphene formed according to the present invention.

In accordance with an embodiment of the present invention, a method for forming graphene includes: introducing a substrate and a carbon-containing reactant source into a chamber; and radiating a laser beam on the substrate to decompose the carbon-containing reactant source and form graphene over the substrate using carbon atoms generated by decomposition of the carbon-containing reactant source.

In accordance with another embodiment of the present invention, a graphene transistor includes: a substrate; a graphene pattern formed over the substrate by first laser beam radiation; source/drain regions provided at ends of the graphene pattern by second laser radiation; a gate insulating film provided between the source/drain regions; and a gate electrode provided over the gate insulating film.

### BRIEF DESCRIPTION OF THE DRAWINGS

FIGS. 1 to 11 show a method for forming graphene according to an embodiment of the present invention.

FIG. 12 shows a method for forming graphene according to another embodiment of the present invention.

FIG. 13 is a graph showing D, G and 2D peaks in a Raman analysis of graphene formed on the SiC substrate.

FIGS. 14 to 26 show a method for forming graphene according to an embodiment of the present invention and a method for forming a transistor using the graphene.

### DESCRIPTION OF SPECIFIC EMBODIMENTS

Exemplary embodiments of the present invention will be described below in more detail with reference to the accompanying drawings. The present invention may, however, be embodied in different forms and should not be construed as being limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention. In the drawings, the width, length, and thickness of an element can be exaggerated to help promote better understanding. Acronyms in this disclosure should be construed as having the meanings generally accepted in the related art unless there is indication to the contrary. In order to form graphene in a large size, the present invention uses a carbon-containing reacting source which is decomposed by a laser beam to provide carbon. The carbon-containing reacting source can be provided in a gaseous state. Also, a carbon-containing substrate can be employed as the carbon-containing reacting source.

Growing Graphene Using Carbon-Containing Reacting Source

A reacting gas containing methane and hydrogen is decomposed to form graphene on a substrate. Considering that the decomposition rate of methane is several seconds, a laser beam with a pulse (nanoseconds) longer than the decomposition rate of methane is employed to decompose the reacting gas, i.e., the gas provided for graphene growth. Because a laser beam can be irradiated within a small area on a substrate, graphene can be formed uniformly in a large scale.

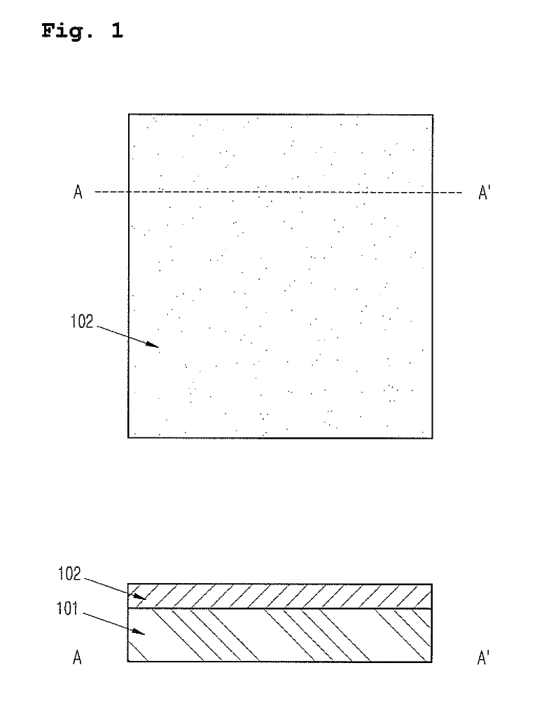

Referring to FIG. 1, a substrate, on which silicon oxide is formed, is provided. More specifically, the substrate may include a silicon oxide layer 102 on the top surface thereof. However, the present invention is not limited to this structure. In one embodiment of the present invention, a silicon substrate will be used as the substrate, but the present invention is not limited to this structure. In place of the silicon substrate, a silicon oxide/silicon substrate, a silicon substrate on which metal is deposited, or copper foil can be used. The substrate functions as a lower supporting layer on which to grow graphene.

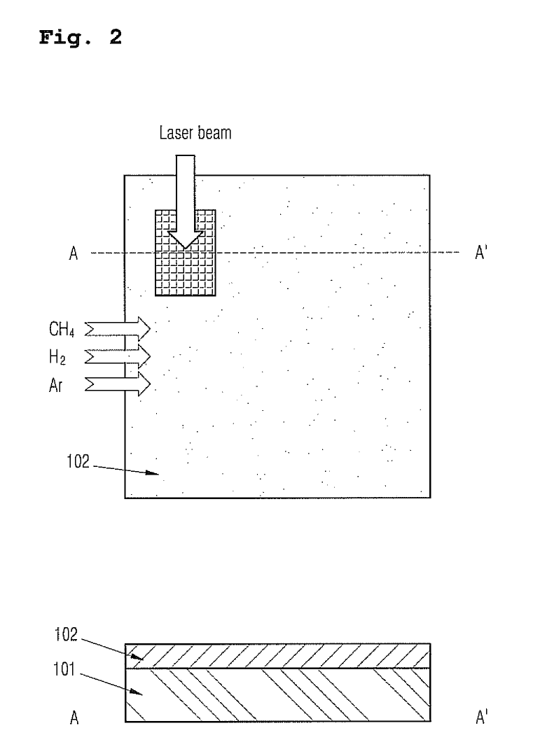

Referring to FIG. 2, a reacting gas including a carbon-containing gas is provided over the silicon oxide layer 102 so that the reacting gas comes into contact with the silicon oxide layer. According to an embodiment of the present invention, the reacting gas includes methane (CH₄), hydrogen (H₂) and an inert gas such as argon (Ar). Methane provides carbon for growing graphene, while hydrogen contributes to creating a reduction atmosphere and prevents the graphene from being oxidized. Then, a laser beam is radiated onto the substrate, which is in contact with the reaction gas. The reacting gas is decomposed by the laser beam, the carbon-containing gas (methane) is decomposed accordingly, and graphene is grown in the area that is subjected to radiation. In this way, methane gas, which has a decomposition rate on the order of femtoseconds, is effectively decomposed on the substrate by a laser beam, which has a pulse on the order of nanoseconds, thereby forming a carbon layer on the substrate.

In an embodiment of the present invention, the power of the laser beam is strong enough to be sufficient to decompose the carbon-containing gas and make the graphene grow. Either a one-dimensional beam or a two-dimensional beam can be employed. Any laser beam can be employed, irrespective of its size, shape or type. When radiated by the laser beam, the substrate is heated up to 800-1200 Celsius degrees, and the methane gas that is in contact with the heated substrate decomposes. Therefore, any laser can be employed for the present invention, irrespective of its type and size, so long as it can raise the temperature of the substrate up to 800-1200 Celsius degrees.

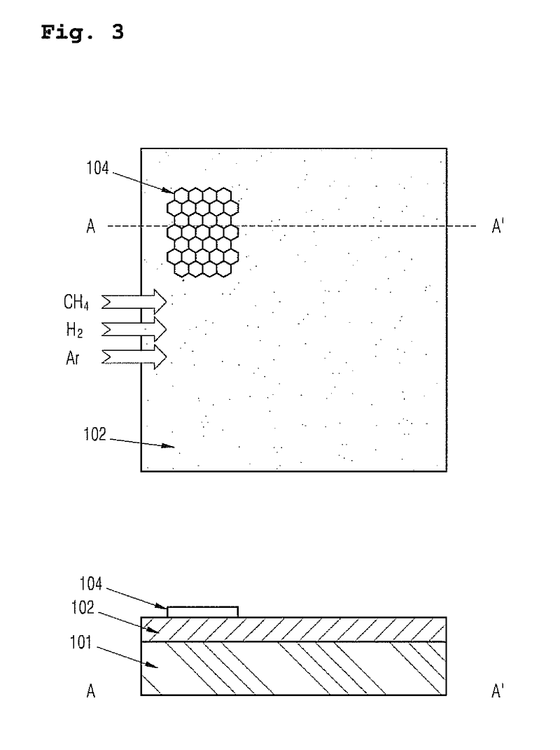

Referring to FIG. 3, graphene 104 is grown on the specific area of the substrate that is irradiated.

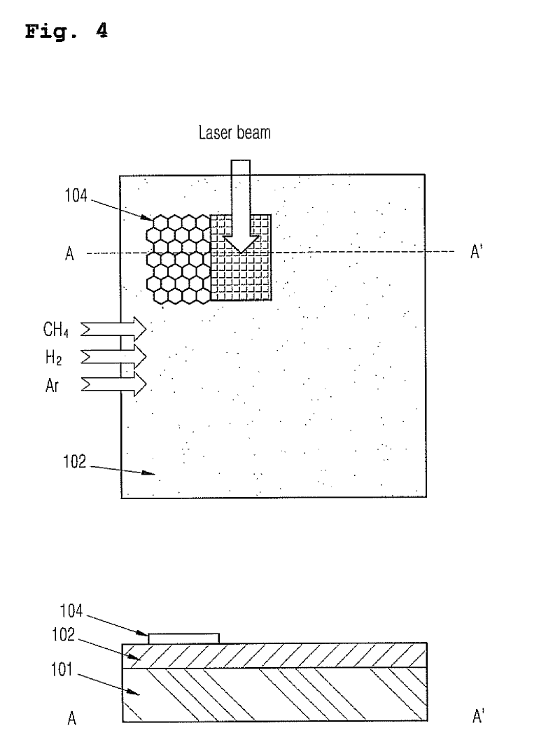

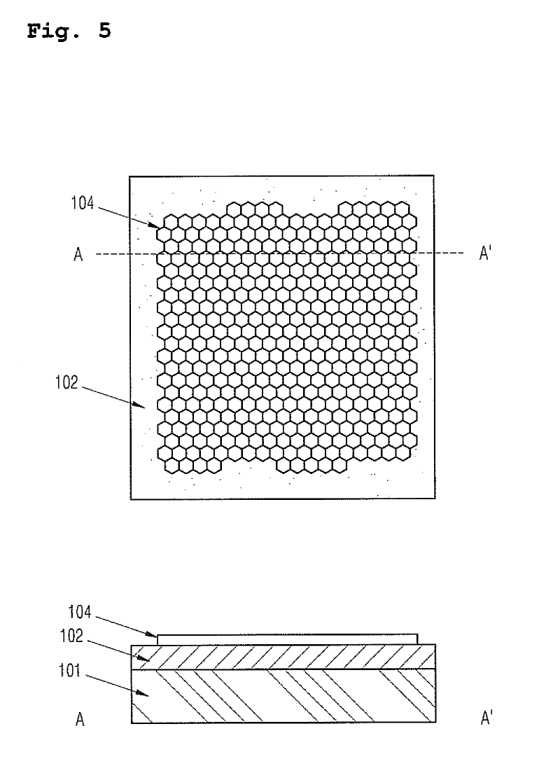

Referring to FIG. 4, when graphene growth in a specific area is completed, the laser beam is radiated on another area. That is, by moving the laser beam and changing the area that is irradiated, graphene 104 is grown accordingly. To change the area that is irradiated, either the laser beam or the substrate can be moved. FIG. 5 shows graphene which is formed on a large scale according to the above-mentioned method.

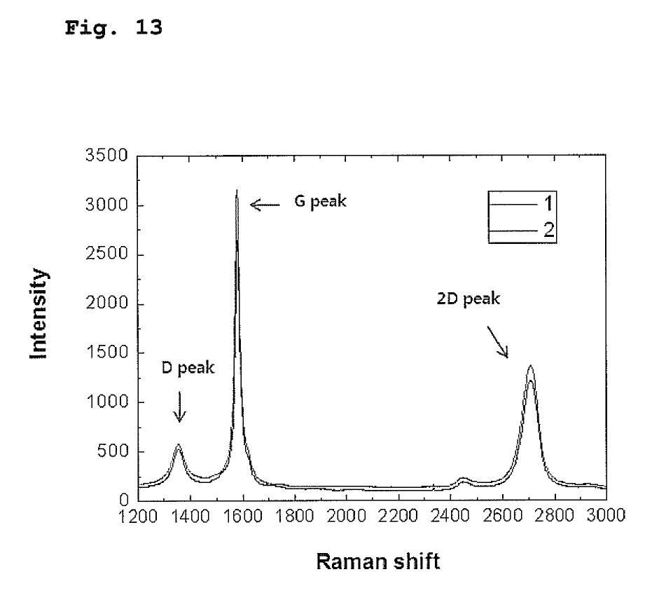

Since the laser beam has a narrow line width, it is possible to precisely control the area on which graphene is grown. For example, by radiating the laser beam twice, areas of graphene 104 can be formed side by side on the substrate. By repeating the same process, graphene 104 can be formed on a large scale on the substrate (silicon oxide) 102. That is, as the number of times the radiation process is conducted is increased, the size of the graphene formed on the substrate is increased. Referring to FIG. 5, the substrate is covered by the graphene in this manner. If necessary, as shown in FIG. 13, selective graphene growth is possible by selectively irradiating the laser beam on the substrate to form a specific pattern of graphene. According to the present invention, a single layer of graphene 104 can be formed on a large scale by selectively decomposing methane gas on the silicon oxide layer 102. The graphene obtained in this way can be used as electrode material or semiconductor material.

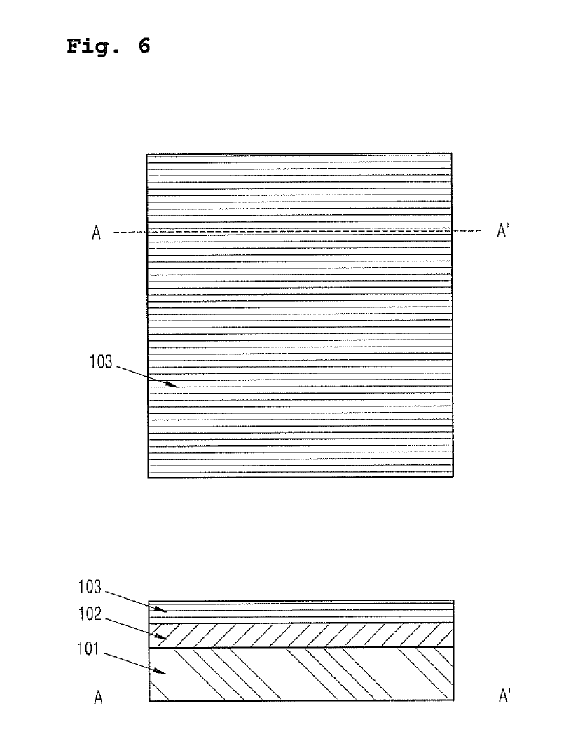

Referring to FIG. 6, a catalyst metal layer 103 may be formed over the silicon oxide layer 102. The catalyst metal layer 103 can facilitate, in combination with the laser beam, decomposition of the reacting gas. The catalyst metal layer 103 may be formed of nickel or copper. By repeating the laser beam radiation process as mentioned above, graphene is formed on the catalyst metal layer 103.

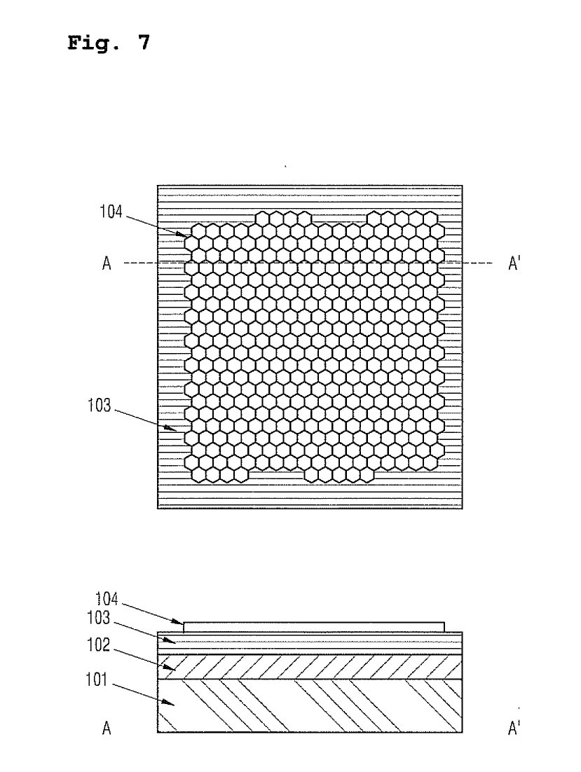

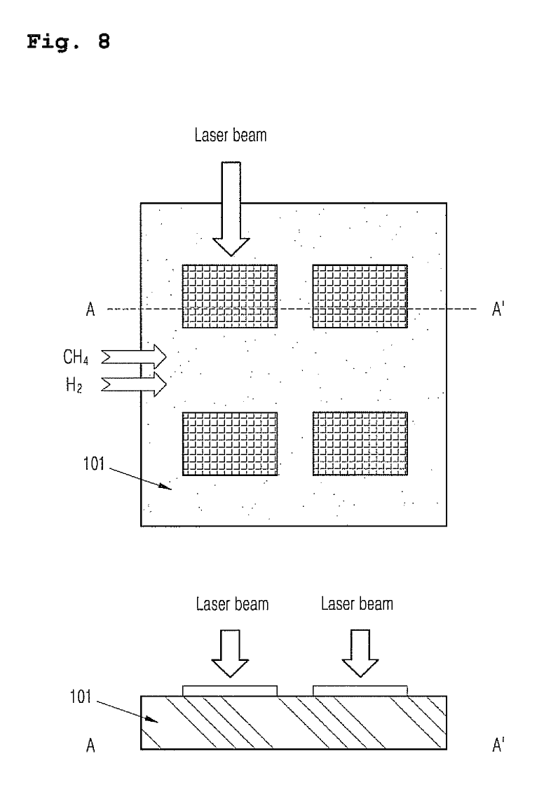

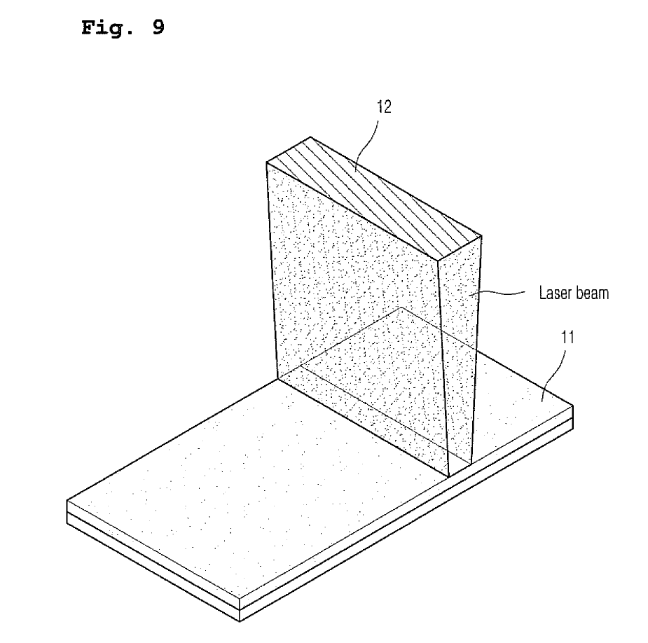

FIG. 7 shows graphene formed on a large scale on the catalyst metal layer 103. Graphene can be formed using a device employing a laser beam, as shown in FIGS. 9-11.

Referring to FIG. 9, the device according to the present invention includes a laser beam radiating means 12 that radiates a laser beam on a substrate 11. The laser beam can be radiated on the substrate in various patterns, that is, the present invention is not limited to the pattern shown in FIG. 9. The substrate may include, as an upper layer, a silicon oxide layer or a catalyst metal layer, as mentioned above.

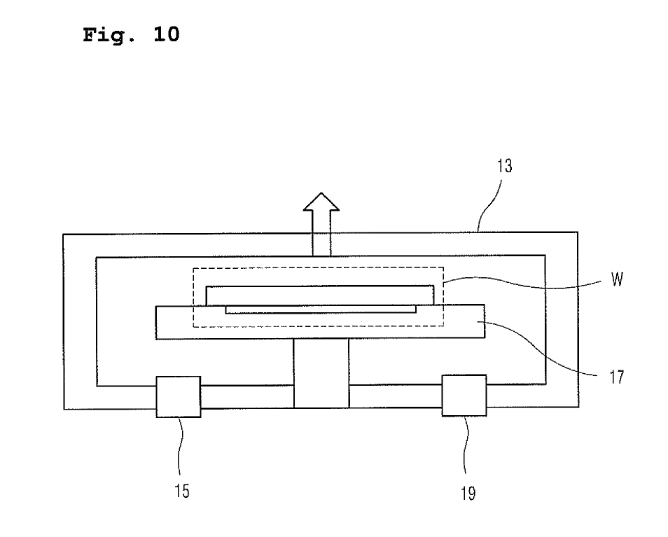

Referring to FIG. 10, a chamber 13 of the graphene manufacturing device according to the present invention may be a vacuum chamber that is isolated from the exterior. The chamber 13 includes a first hole 15, which is coupled to an outside vacuum line (not shown), and a plate 17 on which a substrate w is laid. The plate 17 may include a heating means for raising the temperature of the substrate in order to further heat the substrate and thereby improve the properties of the graphene. A second hole 19 is further formed in the outer wall of the chamber 13 for the introduction of a reacting gas into the inside thereof.

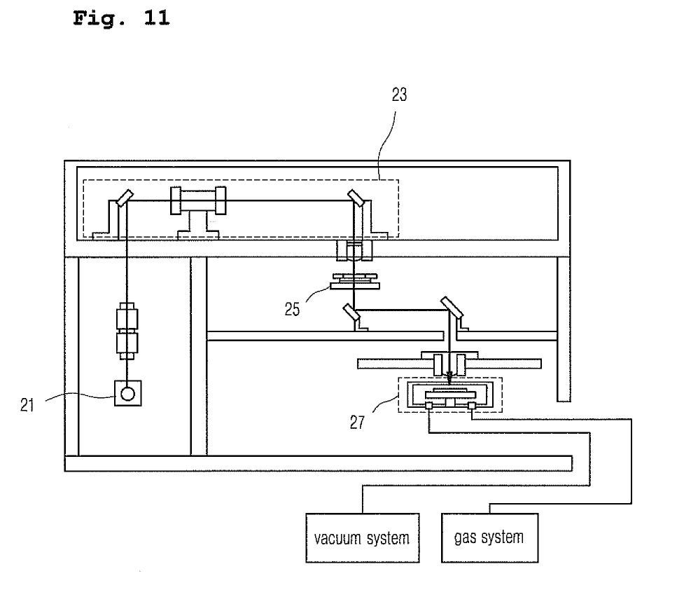

FIG. 11 is a schematic diagram showing a graphene manufacturing device according to an embodiment of the present invention. Referring to FIG. 11, a laser beam generated from a laser beam generator 21 goes through an optical system 23 and a mask stage 25, and is radiated into a chamber 27 in which a substrate is disposed. Like the chamber 13 in FIG. 10, the chamber 27 may be connected to a separate system for providing a reacting gas. The graphene manufacturing device according to the present invention can also include a means for moving the substrate or the laser beam in order to obtain graphene on a large scale. Using this means, graphene can be selectively grown in a desired area. That is, by consecutively and continuously changing the area that is radiated by the laser beam, graphene can be continuously grown on the substrate on a large scale.

Meanwhile, because of its crystalline structure, which is the same as that of graphene, boron nitride is receiving attention as a candidate next-generation electronic material. The boron nitride is usually formed using a chemical vapor deposition method. The present invention uses a substrate on which a boron nitride layer is formed to obtain graphene. In combination with the substrate, the boron nitride layer can form a boron nitride substrate. More specifically, a laser beam is radiated on the substrate while a nitride-containing gas and a boron-containing gas are provided on the substrate. The nitride-containing gas may be NH₃, and the boron-containing gas may be B₂H₆, but these are not limited there to. For example, BCL₃, BF₃ etc. can be employed for the boron-containing gas.

The doping gases in contact with the substrate, which is subjected to radiation, decompose to form a boron-nitride (BN) layer. The BN layer is formed as a result of the nitride-containing gas and the boron-containing gas decomposing at the same time. Therefore, the BN layer is formed on the substrate 101 that is subjected to radiation. By using a graphene manufacturing device according to the present invention and adjusting the radiation time and the radiation area, graphene can be continuously formed at a uniform height in two dimensions. As for the moving means for moving the laser beam or the substrate, any conventional moving means can be employed.

Graphene Growth Using Carbon Provided from a Substrate

The present invention provides a method for forming graphene by radiating a laser beam onto a SiC substrate. When radiated by a laser beam, silicon that is within a given distance from the surface of a substrate is sublimated, and carbon remains. The remaining carbon grows into graphene on the irradiated substrate. This method uses the substrate itself as a carbon source, instead of using a separate carbon source provided from outside. By changing the area that is irradiated by the laser beam, a single layer of graphene can be formed in a desired pattern and on a large scale. If necessary, selective graphene growth can be achieved by controlling the area that is radiated by the laser beam, thereby forming a specific graphene pattern.

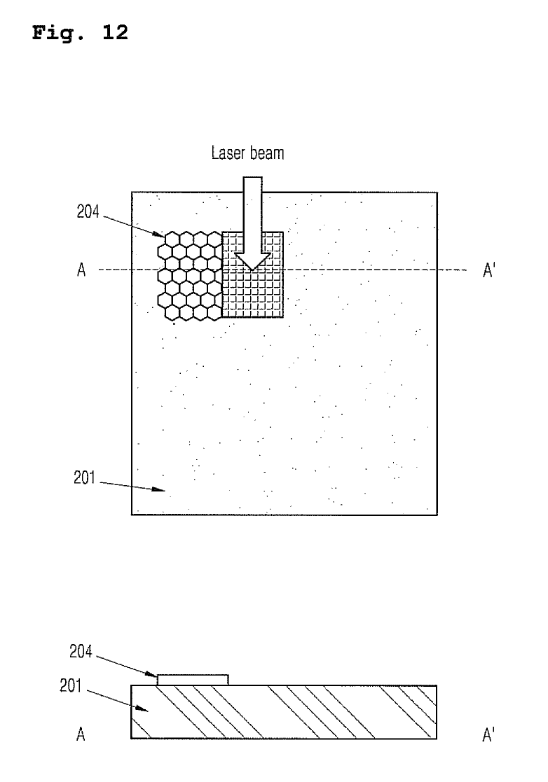

Specifically, referring to FIG. 12, a SiC substrate 201 is provided. The SiC substrate consists of silicon and carbon, which are formed in a crystalline structure. According to the present invention, the SiC substrate 201 is radiated by a laser beam, so that the carbon in the substrate grows into graphene 204. The SiC substrate becomes a carbon source.

According to an embodiment of the present invention, an excimer laser is used, and the radiation time is on the order of nanoseconds. The substrate 201 radiated by the laser beam is heated up to 800-2000 Celsius degrees, and the silicon in the substrate is sublimate. Any laser can be employed for the present invention regardless of its type or its size, as long as it can raise the temperature of the substrate up to 800-2000 Celsius degrees.

The pressure in the substrate where the laser beam is radiated to grow the graphene is maintained at 1.0×10⁻⁵ 1.0×10⁻¹² torr. Preferably, it is maintained at 1.0×10⁻⁵ 1.0×10⁻⁷ torr. FIG. 13 is a graph showing the result of a Raman analysis of graphene formed on the SiC substrate. As shown in FIG. 13, a defect (D) peak is low, a graphite (G) peak is high, and 2-defect (2D) peak is considerably lower than the G peak.

Graphene Pattern

The graphene is selectively removed to form a nano size graphene pattern having the properties of a semiconductor. The patterned graphene is in a nanoribbon shape (corresponding to a channel of a MOS transistor), and the size of the nanoribbon is 10 nm or less. When the width of the nano graphene pattern is 10 nm or less, a band gap exhibiting the properties of a semiconductor is formed. It is difficult to pattern graphene in such a fine size using a conventional semiconductor process or a conventional graphene manufacturing method. In contrast, a process using a laser beam, which is precisely controllable, can make it possible to form such a fine pattern.

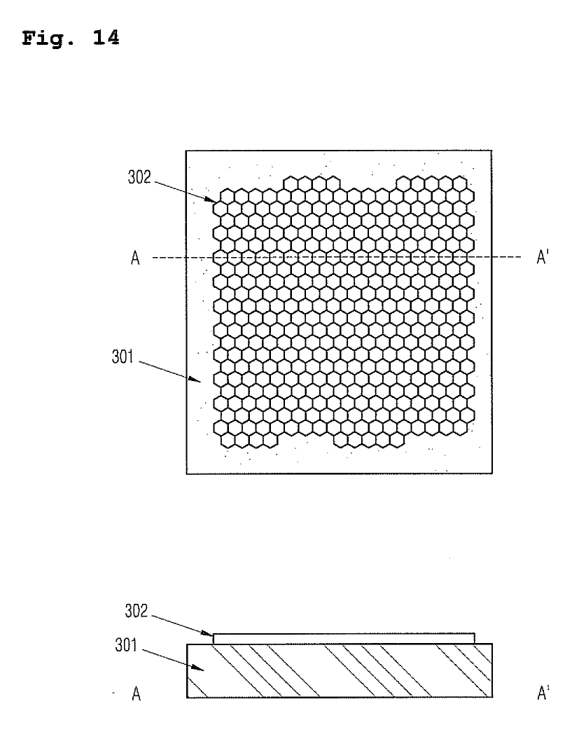

FIG. 14 shows a SiC substrate 301 having graphene 302 on the top. The graphene is formed using a carbon-containing gas. The graphene can be formed on the entire surface of the substrate, or on part of the substrate.

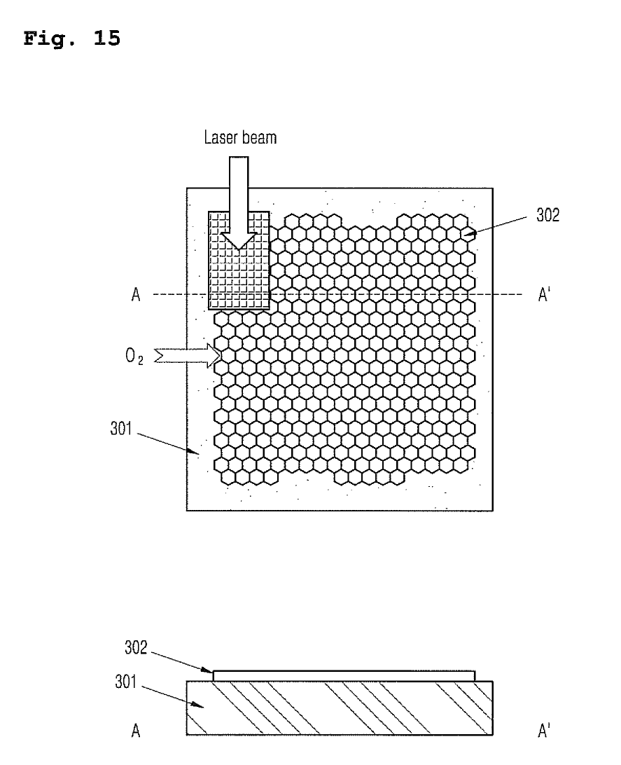

Referring to FIG. 15, a laser beam is radiated on the single layer of graphene 302 in an oxygen atmosphere. The oxygen atmosphere can consist solely of oxygen, or of a mixture gas containing oxygen.

The graphene 302, which has been subjected to radiation in an oxygen atmosphere, is removed. The region where the graphene is removed is the region where the laser beam was radiated.

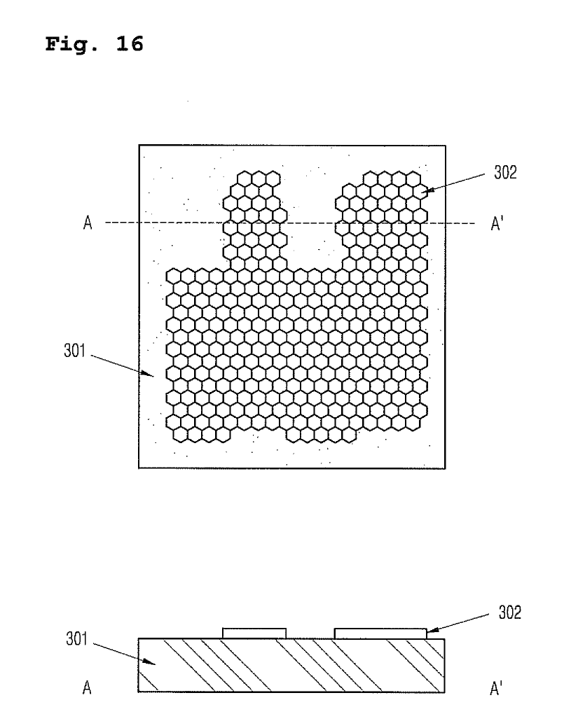

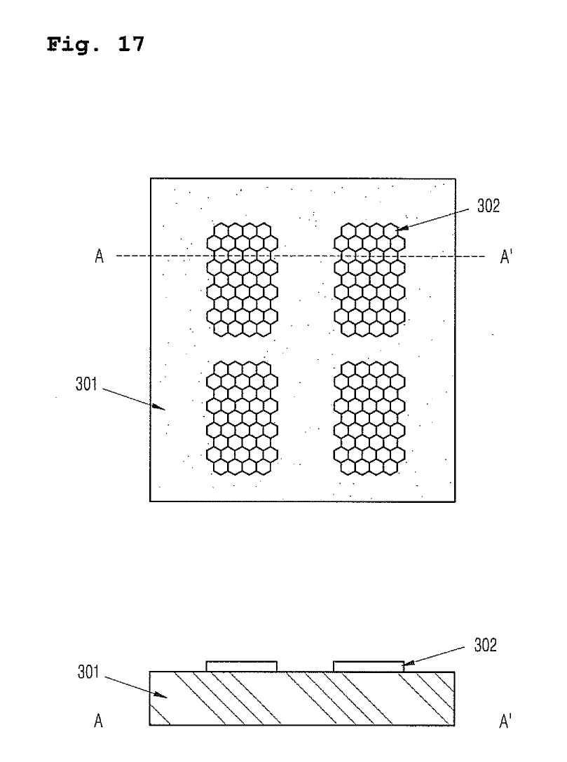

Referring to FIG. 16, the laser beam radiation process continues to selectively remove graphene until the desired pattern, shown in FIG. 17 (a rectangular pattern), is obtained. In order to form a band gap exhibiting the properties of a semiconductor, the present inventors found that the size of the graphene pattern should be 10 nm or less.

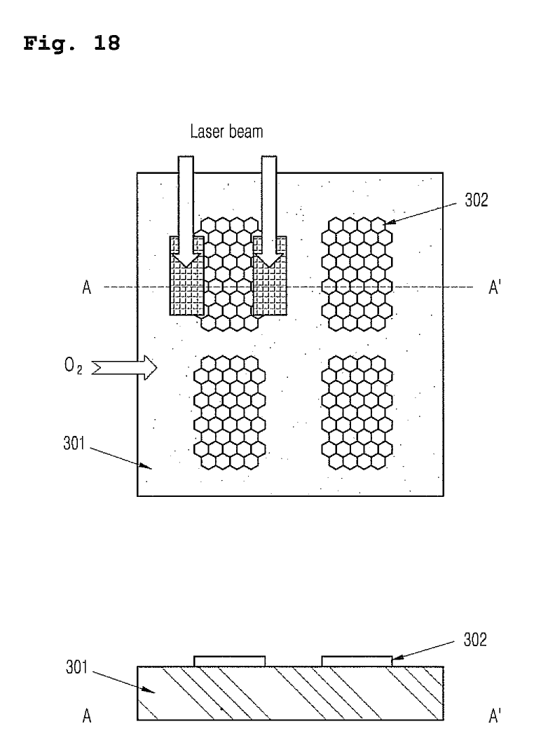

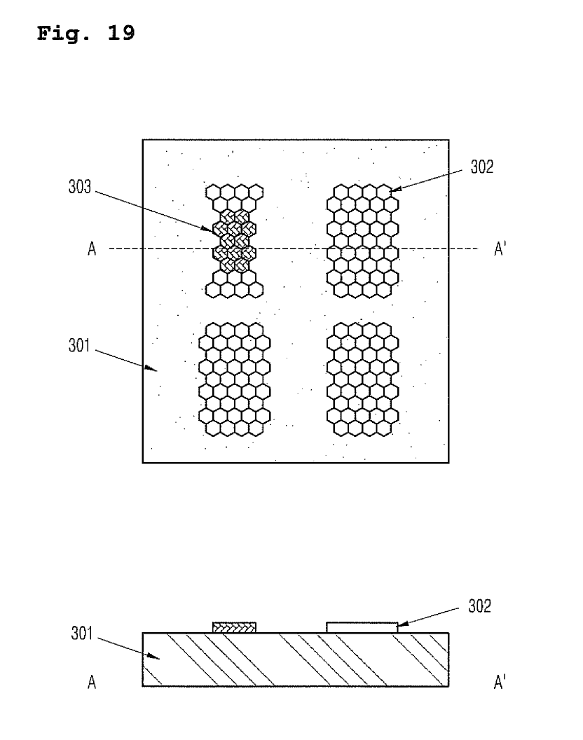

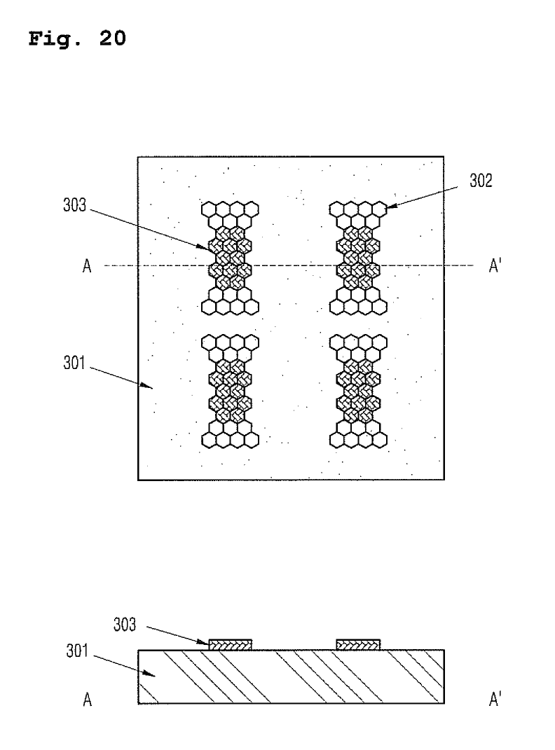

Referring to FIGS. 18-20, 4 graphene patterns are subject to selective radiation to form graphene semiconductor devices 303 of 10 nm width or less.

According to the present invention, both processes of forming and patterning the graphene are performed using laser beams (a first laser beam radiation step and a second laser beam radiation step) to form a graphene semiconductor device.

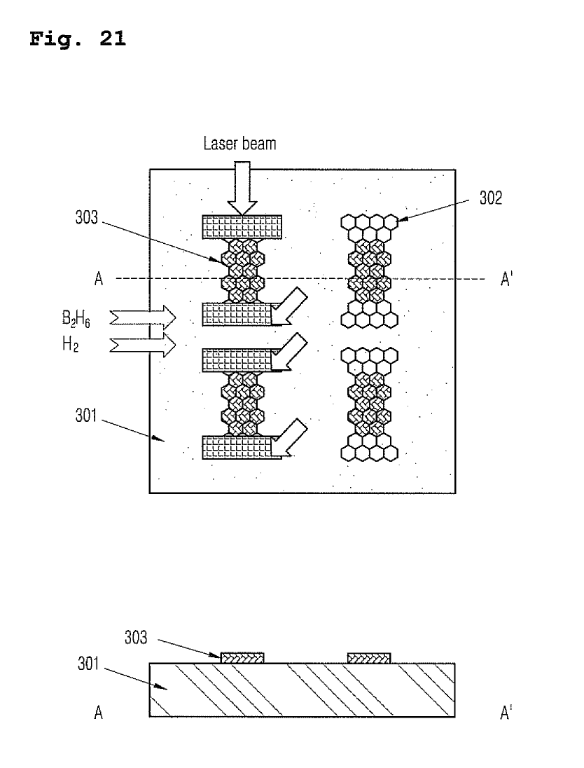

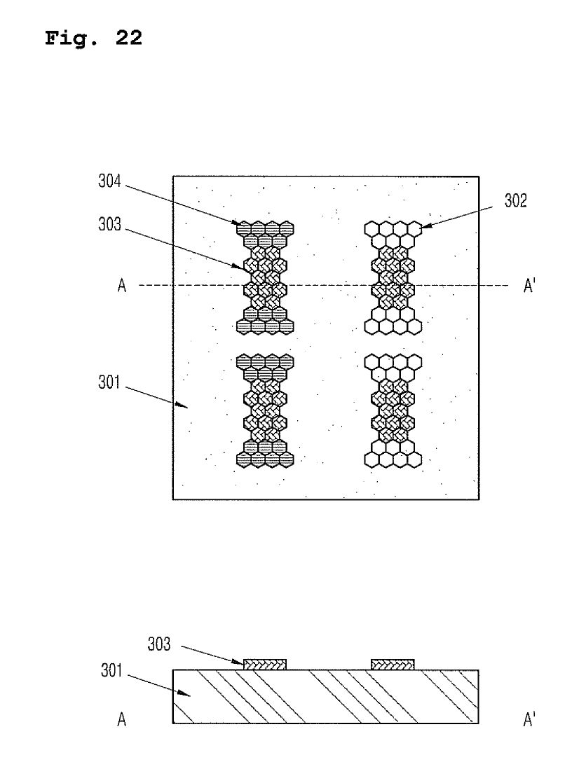

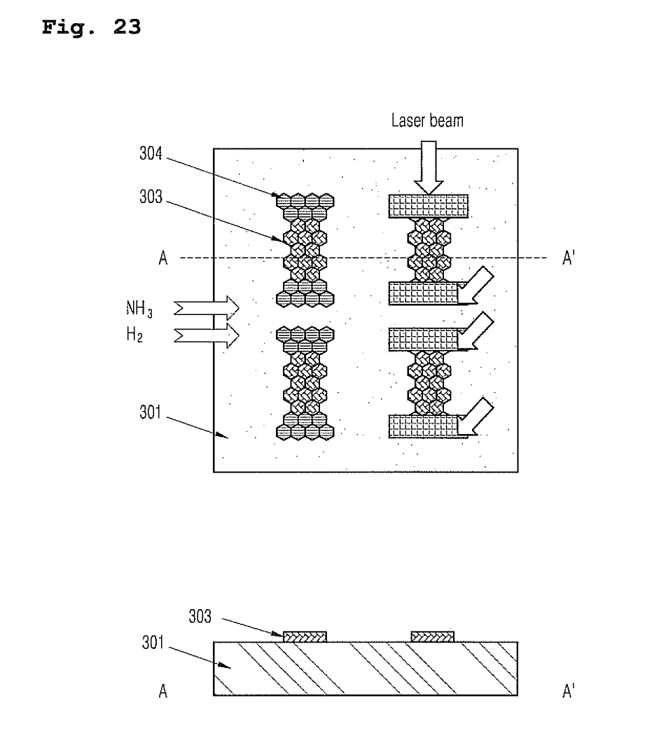

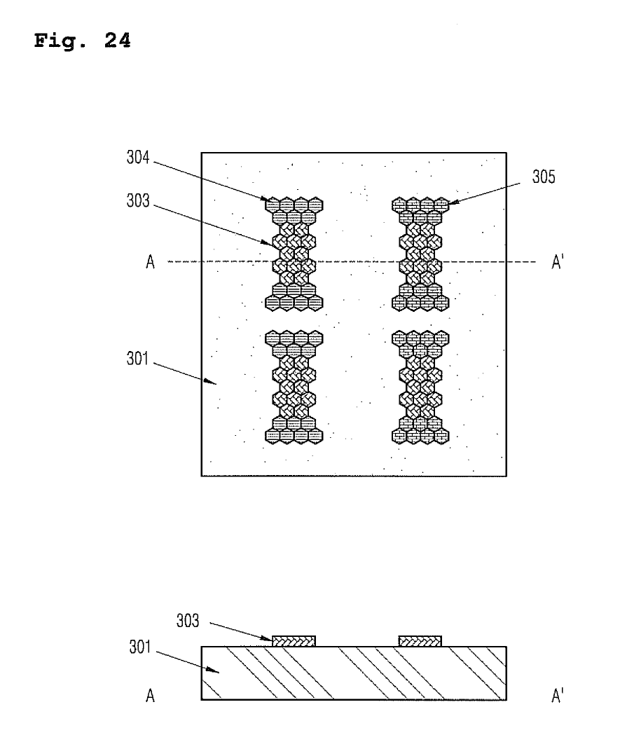

Referring FIGS. 21-24, a boron-containing doping gas (B₂H₆, methane) is provided to the graphene pattern, and a laser beam is simultaneously radiated at both ends of the graphene pattern (a third laser beam radiation step). As a result, doping regions 304 are formed at both ends of the ribbon-shaped graphene pattern. In the same manner, nitrogen doping is performed by providing a doping gas, which contains both NH₃ and methane, and simultaneously radiating a laser on a desired area of the graphene pattern.

In this manner, four nanoribbon graphene devices are obtained. Two of them, located at the left hand side, have boron-doped regions 304 at both ends, while the remaining two of them, located at the right hand side, have nitrogen-doped regions 305. The doped regions 304 and 305 serve as sources or drains of a graphene transistor.

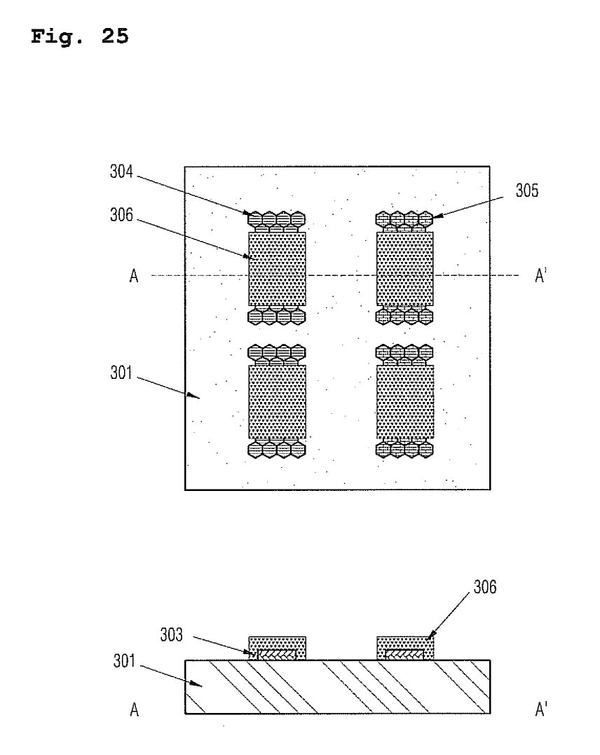

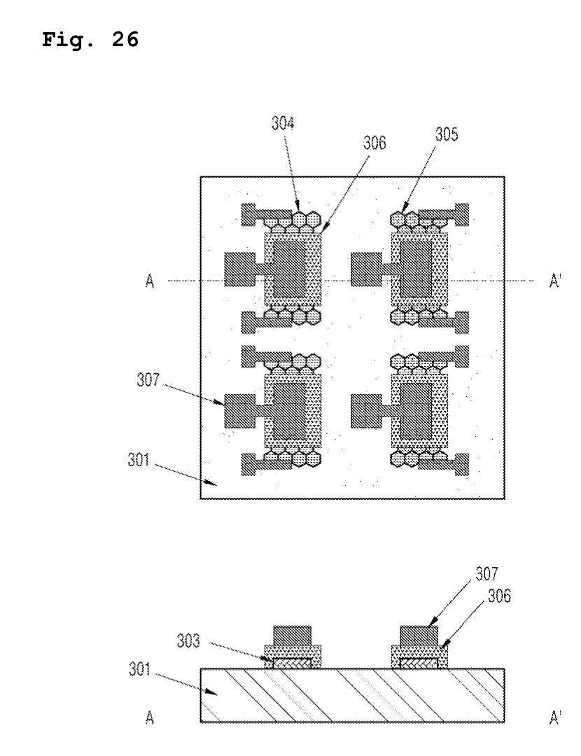

Referring to FIG. 25, an insulating film 306 such as HfO₂ is formed on the graphene between the doped regions 304 and 305 to form a transistor. The insulating film 306 serves as a gate insulating film. Referring to FIG. 26, a metal layer 307 is formed and then patterned over the doped regions (the source and the drain) and over the gate insulating film. As a result, a graphene transistor is obtained. The doped regions 304 and 305 are coupled to source and drain electrodes, respectively. A gate electrode is formed over the gate insulating film. While a SiC substrate is used in this embodiment, the present invention is not limited thereto. A substrate having a silicon oxide layer or a catalyst layer on the top can also be used.

In accordance with another embodiment of the present invention, carbon-containing gas (methane), of which the decomposition rate is on the order of femtoseconds, is decomposed using a laser beam, which has a pulse on the order of nanoseconds to form graphene. Using this method, graphene is formed in a large size. Also, a desired graphene pattern can be obtained by selectively radiating the laser beam on a desired region of the substrate. Using this graphene pattern, a semiconductor device and a transistor can be manufactured.

While the present invention has been described with respect to specific embodiments thereof, it will be apparent to those skilled in the art that various changes and modifications may be made without departing from the spirit and scope of the invention as defined in the following claims.

What is claimed is:

1. A method for forming graphene, comprising:
providing a substrate and a carbon-containing reactant source in a chamber; and
radiating a laser beam on the substrate to decompose the carbon-containing reactant source and form graphene over the substrate using carbon atoms generated by decomposition of the carbon-containing reactant source.

2. The method of claim 1, further comprising:
providing hydrogen gas into the chamber to create a reduction atmosphere.

3. The method of claim 1, wherein the substrate includes a silicon oxide layer, and wherein the graphene is formed over the silicon oxide layer.

4. The method of claim 1, wherein the carbon-containing reactant source is a mixture gas including methane, hydrogen, and an inert gas, and wherein the methane decomposes when the laser beam is radiated to generate the carbon atoms.

5. The method of claim 4, wherein the substrate is maintained at 800-1200 Celsius degrees when the graphene is formed.

6. The method of claim 1, wherein a metal catalyst layer is formed over the substrate, and
wherein the graphene is formed over the metal catalyst layer.

7. The method of claim 1, further comprising:
patterning the graphene formed over the substrate,
wherein the patterning is performed by radiating the laser beam at an oxygen atmosphere.

8. The method of claim 1, wherein the substrate comprises a boron nitride layer, and wherein the graphene is formed over the boron nitride layer.

9. The method of claim 8, wherein the boron nitride is formed by radiating the laser beam on the substrate while providing a boron-containing doping gas and a nitride-containing doping gas.

10. The method of claim 7, wherein the patterning the graphene results in a ribbon pattern 10 nm wide or less at the center.

11. A method for forming graphene, comprising:
providing a SiC substrate in a chamber;
radiating a laser beam on the SiC substrate and decomposing a surface of the SIC; and
sublimating decomposed silicon atoms and form graphene on the SiC substrate using decomposed carbon atoms.

12. The method of claim 11, wherein a pressure in the chamber is 1.0×10⁻⁵˜1.0×10⁻¹² torr.

13. The method of claim 12, wherein the SiC substrate is maintained at 800-2000 Celsius degrees when the graphene is formed.

14. The method of claim 11, wherein the graphene grows along an illumination region of the laser beam.

15. A method for forming a graphene semiconductor device with a doping region, comprising:
bringing dopant-containing material into contact with graphene; and
radiating a laser beam to form the doping region in the graphene.

16. A graphene transistor, comprising:
a substrate;
a graphene pattern formed over the substrate by first laser beam radiation;
source/drain regions provided at ends of the graphene pattern by second laser radiation;
a gate insulating film provided between the source/drain regions; and
a gate electrode provided over the gate insulating film.

17. The graphene transistor of claim 16, wherein the graphene pattern includes a nanoribbon channel,
wherein the channel is 10 nm or less wide.

18. The graphene transistor of claim 17, wherein the substrate is a SiC substrate.

19. The graphene transistor of claim 17, wherein the substrate includes a boron nitride layer, and wherein the graphene pattern is formed over the boron nitride layer.
